(19) United States
(12) Patent Application Publication
(10) Pub. No.: US 2025/0323108 A1
(43) Pub. Date: Oct. 16, 2025

(54) SEMICONDUCTOR PACKAGE HAVING ULTRA-THIN SUBSTRATE AND METHOD OF MAKING THE SAME

(71) Applicant: ALPHA AND OMEGA SEMICONDUCTOR INTERNATIONAL LP, TORONTO (CA)

(72) Inventors: Lin Lv, Shanghai (CN); Zhen Yang, Kunshan (CN); Shuhua Zhou, Shanghai (CN); Long-Ching Wang, Cupertino, CA (US)

(73) Assignee: ALPHA AND OMEGA SEMICONDUCTOR INTERNATIONAL LP, TORONTO (CA)

(21) Appl. No.: 18/631,078

(22) Filed: Apr. 10, 2024

(51) Int. Cl. H01L 23/31; H01L 21/304; H01L 21/768; H01L 23/00; H01L 23/532

(52) U.S. Cl. CPC H01L 23/3114; H01L 21/304; H01L 21/76871; H01L 23/53238; H01L 23/53252; H01L 24/05; H01L 24/08; H01L 2224/05144; H01L 2224/05155; H01L 2224/08225; H01L 2924/13091

(57) ABSTRACT

A semiconductor package comprises a semiconductor substrate, a plurality of contact pads, a seed layer, a metal support, and a molding encapsulation. A thickness of the semiconductor substrate is in a range from 15 microns to 35 microns. A thickness of the metal support is at least 30 microns. A method comprises the steps of providing a device wafer; attaching a carrier; applying a thinning process; forming a seed layer; forming a plurality of metal supports; forming a molding encapsulation; and applying a singulation process. The molding encapsulation directly contacts a plurality of side surfaces and a back surface of the metal support to facilitate efficient saw blade cutting.

### FIELD OF THE INVENTION

This invention relates generally to a semiconductor package having a thin semiconductor substrate of less than 50 microns and a method of making a plurality of semiconductor packages. More particularly, the present invention relates to a semiconductor package, operative in a sufficient safety factor range, having a substrate with a thickness in a range from 15 microns to 35 microns.

### BACKGROUND OF THE INVENTION

While mobile phone manufactures and consumers continue in demanding higher charging current, ultra-low resistance products, including ultra-low resistance wafer level chip scale package (WL-CSP) power chips are required to improve battery performance. In general, a silicon layer (semiconductor silicon substrate) of a WL-CSP power chip contributes most of the conduction impedance, direct current (DC) resistance. It is most effective to reduce a thickness of the semiconductor silicon substrate and to increase a thickness of a metal support of a WL-CSP power chip, including a common-drain metal-oxide-semiconductor field-effect transistor (MOSFET) CSP, to reduce the conduction impedance. Conventional MOSFET-CSP for battery protection application usually includes a semiconductor silicon substrate having a thickness of 75 microns or more. It is advantageous to reduce the semiconductor silicon substrate thickness to be 35 microns or less so as to reduce the DC resistance and to increase the electrical performance.

U.S. Pat. No. 10,991,660 and US Patent Application Publication No. 2019/0189569 to Wang et al. disclose a semiconductor package having a thickness of the semiconductor substrate equal to or less than 50 microns. U.S. Pat. No. 11,495,548 and US Patent Application Publication No. 2021/0125940 to Lu et al. disclose a semiconductor package having a thickness of the semiconductor substrate equal to or less than 75 microns. U.S. Pat. No. 11,784,141 and US Patent Application Publication No. 2023/0021687 to Lu et al. disclose a semiconductor package having a thickness of the semiconductor substrate equal to or less than 75 microns.

The on-resistance can be reduced by 24% when the thickness of the semiconductor substrate is reduced from 50 microns to 25 microns. The mechanical strength of the semiconductor package decreases when the semiconductor substrate thickness decreases. In examples of the present disclosure, a thickness of a metal support of at least 30 microns facilitates the semiconductor package re-gaining the mechanical strength so as to maintain low warpage, less delamination, low cost, and efficient saw blade cutting.

### SUMMARY OF THE INVENTION

A semiconductor package comprises a semiconductor substrate, a plurality of contact pads, a seed layer, a metal support, and a molding encapsulation. A thickness of the semiconductor substrate is less than 50 microns, preferable in a range from 15 microns to 35 microns. A thickness of the metal support is at least 30 microns.

A method for fabricating a plurality of semiconductor packages is disclosed. The method comprising the steps of providing a device wafer; attaching a carrier; applying a thinning process; forming a seed layer; forming a plurality of metal supports; forming a molding encapsulation; and applying a singulation process. The molding encapsulation directly contacts a plurality of side surfaces and a back surface of the metal support to facilitate efficient saw blade cutting.

### BRIEF DESCRIPTION OF THE DRAWINGS

FIG. 1 shows a cross-sectional view of a semiconductor package in examples of the present disclosure.

FIG. 2 is a flowchart of a process to develop a plurality of semiconductor packages in examples of the present disclosure.

FIGS. 3A, 3B, 3C, 3D, 3E, 3F, 3G, 3H, 3I, 3J, 3K, and 3L show the cross sections of the corresponding steps of the process of FIG. 2 in examples of the present disclosure.

### DETAILED DESCRIPTION OF THE INVENTION

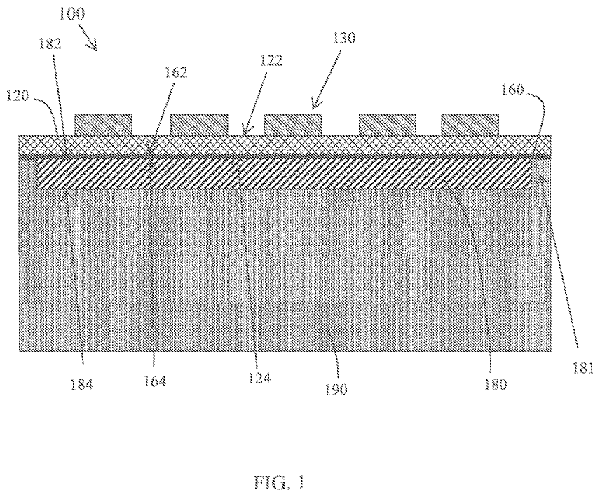

FIG. 1 shows a cross-sectional view of a semiconductor package 100 in examples of the present disclosure. The semiconductor package 100 comprises a semiconductor substrate 120, a plurality of contact pads 130, a seed layer 160, a metal support 180, and a molding encapsulation 190. In examples of the present disclosure, all edges of the metal support 180 recess from corresponding edges of the seed layer 160.

The semiconductor substrate 120 has a front surface 122 and a back surface 124 opposite the front surface 122 of the semiconductor substrate 120. The plurality of contact pads 130 are attached to the front surface 122 of the semiconductor substrate 120. The seed layer 160 has a front surface 162 and a back surface 164 opposite the front surface 162 of the seed layer 160. The front surface 162 of the seed layer 160 is directly attached to the back surface 124 of the semiconductor substrate 120. All edges of the seed layer 160 align to corresponding edges of the semiconductor substrate 120.

The metal support 180 has a plurality of side surfaces 181, a front surface 182, and a back surface 184 opposite the front surface 182 of the metal support 180. The front surface 182 of the metal support 180 is directly attached to the back surface 164 of the seed layer 160. The plurality of side surfaces 181 define edges of the metal support 180. All edges of the metal support 180 recess from corresponding edges of the seed layer 160 in a range from 5 to 50 microns. The molding encapsulation 190 directly contacts the plurality of side surfaces 181 and the back surface 184 of the metal support 180. Edges of the molding encapsulation 190 align to the corresponding edges of the seed layer 160 and the corresponding edges of the semiconductor substrate 120. In examples of the present disclosure, the molding encapsulation 190 directly contacts the back surface 164 of the seed layer 160 in the area not covered by the metal support 180.

In examples of the present disclosure, a thickness of the semiconductor substrate 120 is less than 50 microns, preferable in a range from 15 microns to 35 microns. A thickness of the metal support 180 is at least 30 microns.

In examples of the present disclosure, the seed layer 160 is composed of titanium formed by sputtering. A thickness of the seed layer 160 is in a range from 0.4 micron to 1.3 microns. The metal support 180 is composed of copper (Cu), silver (Ag), solder (SnAg), or tin (Sn). In one example, the metal support 180 is composed of copper, the seed layer 160 includes TiCu where a thickness of Ti formed by sputtering is in a range from 0.1 micron to 0.3 micron and a thickness of Cu formed by sputtering is in a range from 0.3 micron to 1 micron. In another example, the metal support 180 is composed of silver, the seed layer 160 includes TiNi where a thickness of Ti formed by sputtering is in a range from 0.1 micron to 0.3 micron and a thickness of Ni formed by sputtering is in a range from 0.3 micron to 1 micron. Each of the plurality of contact pads 130 contains nickel and gold.

In examples of the present disclosure, the semiconductor package 100 is a common-drain metal-oxide-semiconductor field-effect transistor (MOSFET) chip scale package (CSP) for battery protection application. Two gates and a plurality of sources are on a front surface of the common-drain MOSFET CSP. A common-drain is on a back surface of the common-drain MOSFET CSP.

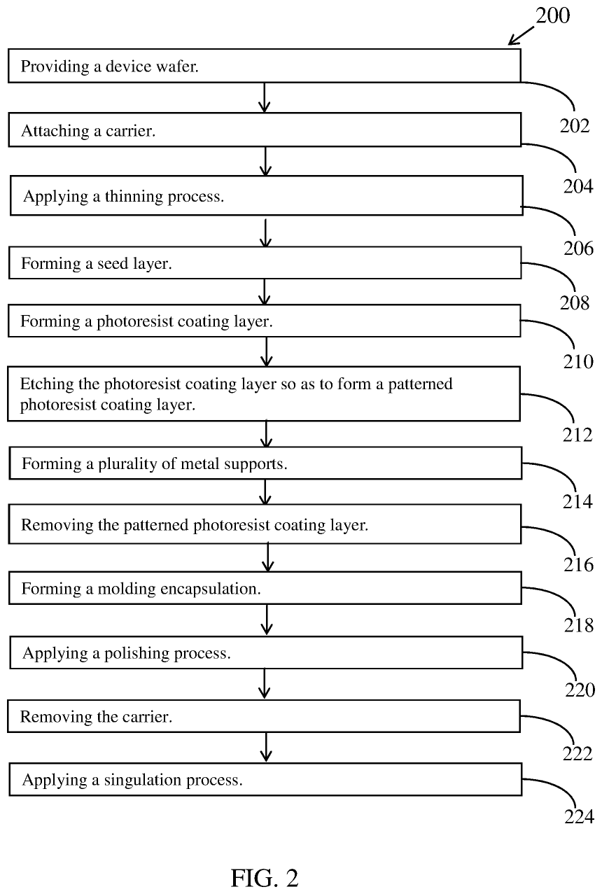

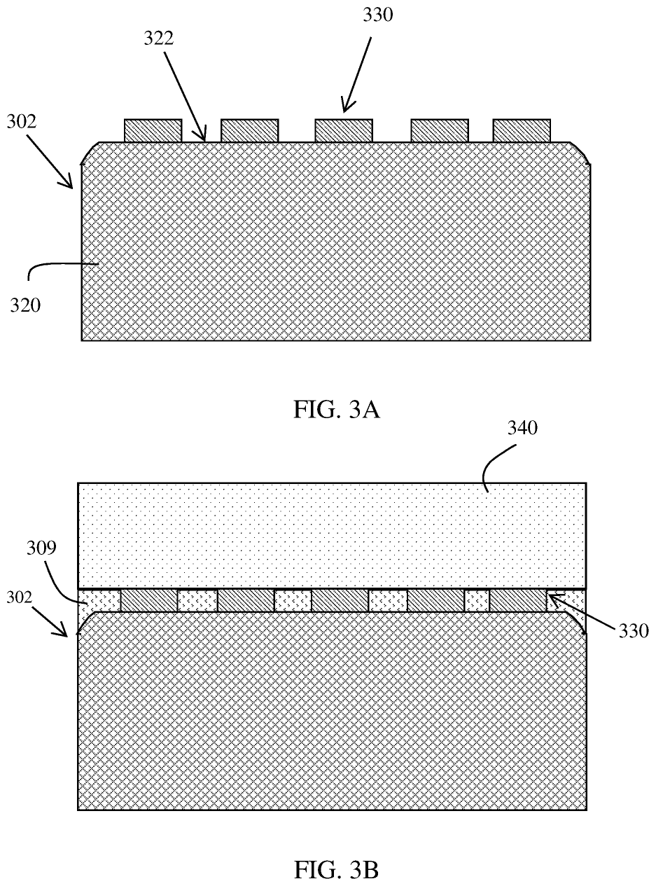

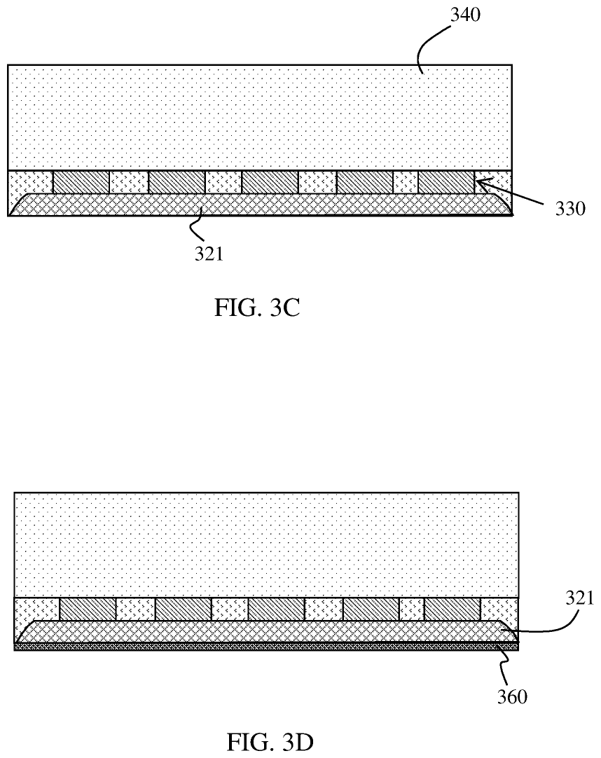

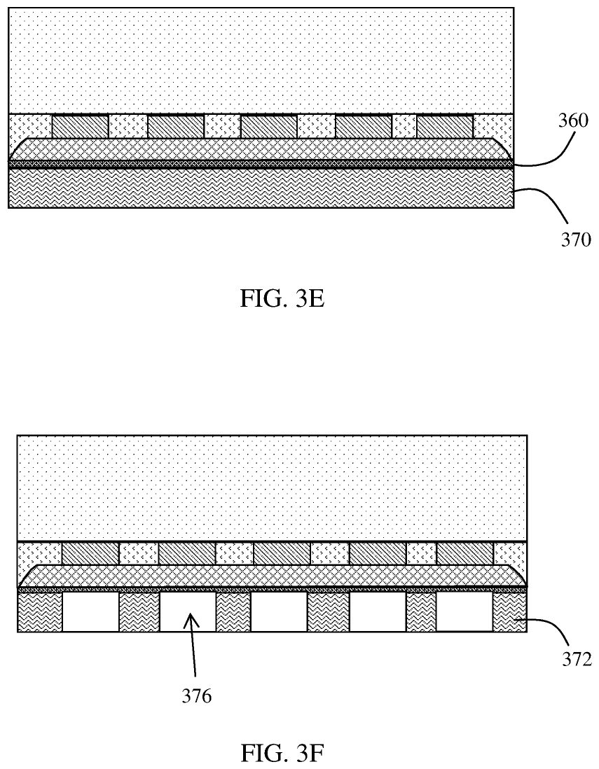

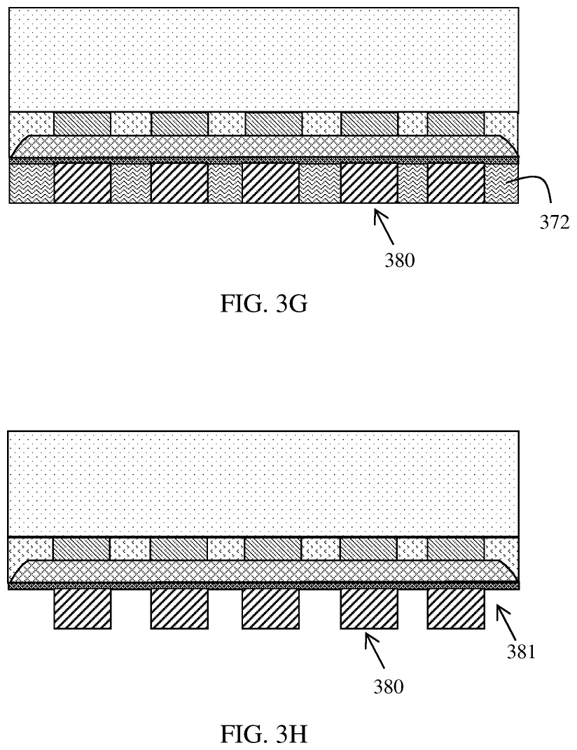

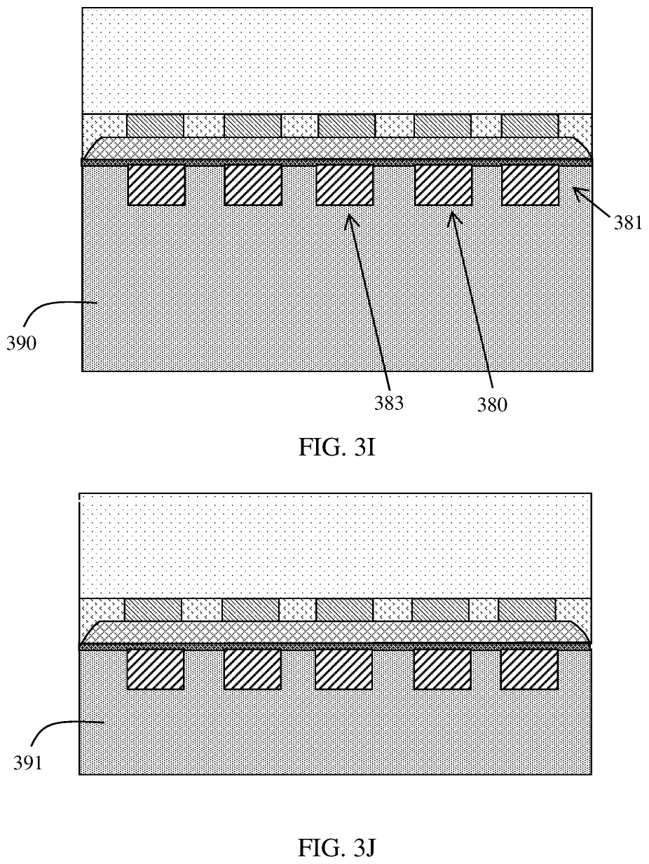

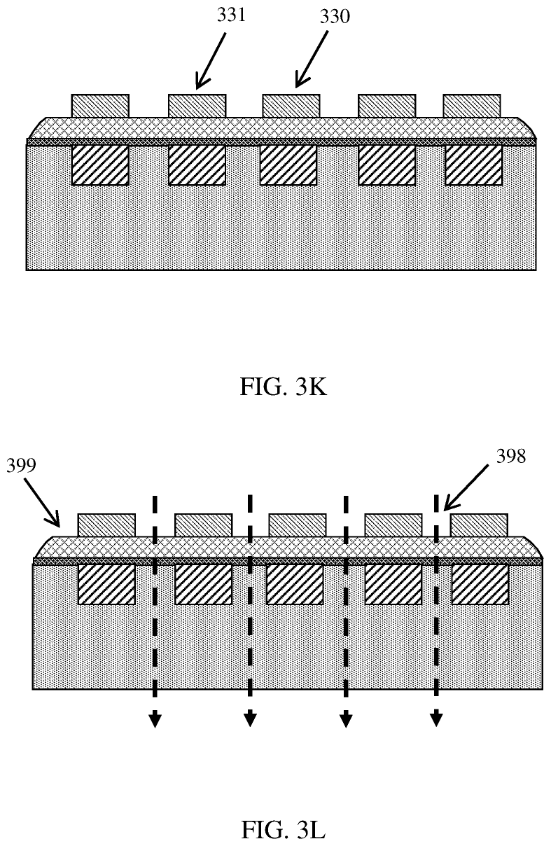

FIG. 2 is a flowchart of a process 200 to develop a plurality of semiconductor packages in examples of the present disclosure. FIGS. 3A, 3B, 3C, 3D, 3E, 3F, 3G, 3H, 3I, 3J, 3K, and 3L show the cross sections of the corresponding steps of the process 200 of FIG. 2 in examples of the present disclosure. The process 200 may start from block 202.

In block 202, referring now to FIG. 3A, a device wafer 302 is provided. The device wafer 302 comprises a semiconductor substrate 320 having a plurality of semiconductor devices formed thereon. Each semiconductor devices may have one or more contact pads 330 for providing connections to the electrodes of the semiconductor devices. Similar to FIG. 3A of US Patent Application Publication No. 2019/0189569, each of the plurality of contact pads 330 may comprise an aluminum layer and a nickel-gold layer. The semiconductor substrate 320 has a front surface 322 and a back surface 324 opposite the front surface 322 of the semiconductor substrate 320. The plurality of contact pads 330 are attached to the front surface 322 of the semiconductor substrate 320. A plurality of scribe lines (not shown) disposed at the front surface of the device wafer separate adjacent semiconductor devices from each other. Block 202 may be followed by block 204.

In block 204, referring now to FIG. 5B, a carrier 340 is attached to the plurality of contact pads 330 of the device wafer 302. In examples of the present disclosure, the attachment is by an adhesive layer 309. The adhesive layer 309 is transparent. The adhesive layer 309 surrounds and protects the plurality of contact pads 330. In one example, the carrier 340 is composed of a metal material. In another example, the carrier 340 is composed of a glass material. The attachment of the carrier 340 will increase the strength of the device wafer 302 so as to reduce warpage during subsequent processing steps. Block 204 may be followed by block 206.

In block 206, referring now to FIG. 3C, a thinning process is applied over the back surface 324 of the semiconductor substrate 320 so as to formed a thinned semiconductor substrate 321. In examples of the present disclosure, a thickness of the thinned semiconductor substrate 321 is in a range from 15 microns to 35 microns. The thinning process may include back side grinding and back side etching. Block 206 may be followed by block 208.

In block 208, referring now to FIG. 3D, a seed layer 360 is formed on the thinned semiconductor substrate 321. The seed layer 360 may be formed by sputtering. In one example, the seed layer 360 contains titanium. A thickness of the seed layer 360 is in a range from 0.4 micron to 1.3 microns. The seed layer 360 covers the entire device wafer back surface. Block 208 may be followed by block 210.

In block 210, referring now to FIG. 3E, a photoresist coating layer 370 is formed on the seed layer 360. Block 210 may be followed by block 212.

In block 212, referring now to FIG. 3F, the photoresist coating layer 370 is etched so as to form a patterned photoresist coating layer 372 comprising a plurality of recesses 376 exposing the seed layer 360. The remaining portions of patterned photoresist coating layer 372 align to the device scribe lines at the front of the device wafer, each having a width wider than the corresponding scribed line. The etching of the photoresist coating layer may include lithographic exposure and developing. Block 212 may be followed by block 214.

In block 214, referring now to FIG. 3G, a plurality of metal supports 380 are formed in the plurality of recesses 376 of the patterned photoresist coating layer 372. In examples of the present disclosure, each back surface of the plurality of metal supports 380 and each back surface of the patterned photoresist coating layer 372 are co-planer. In examples of the present disclosure, a thickness of each of the plurality of metal supports 380 is at least 30 microns. In one example, the plurality of metal supports 380 contain copper formed by electrochemical plating. In another example, the plurality of metal supports 380 contain silver or solder formed by electrochemical plating. Block 214 may be followed by block 216.

In block 216, referring now to FIG. 3H, the patterned photoresist coating layer 372 is removed so as to expose side surfaces 381 of the plurality of metal supports 380. In one example, the step of removing the patterned photoresist coating layer 372 includes stripping. Block 216 may be followed by block 218.

In block 218, referring now to FIG. 3I, a molding encapsulation 390 is formed. The molding encapsulation 390 directly contacts the side surfaces 381 of the plurality of metal supports 380 and back surfaces 383 of the plurality of metal supports 380. The molding encapsulation 390 prevents the back surface 383 of the plurality of metal supports 380 from oxidation. Block 218 may be followed by block 220.

In block 220, referring now to FIG. 3J, a polishing process is applied over a back surface of the molding encapsulation 390 so as to form a polished molding encapsulation 391. A thickness of the molding encapsulation 390 is larger than a thickness of the polished molding encapsulation 391. Block 220 may be followed by block 222.

In block 222, referring now to FIG. 3K, the carrier 340 is removed. The carrier 340 may be removed by a de-bonding process. Top surfaces 331 of the plurality of contact pads 330 are exposed. Block 222 may be followed by block 224.

In block 224, referring now to FIG. 3L, a singulation process, along the scribe lines 398, is provided to cut through the semiconductor substrate, the seed layer and the molding encapsulation in each area between adjacent metal supports so that a plurality of semiconductor packages 399 are formed. The molding encapsulation 390 of FIG. 3I directly contacts a plurality of side surfaces 381 and a back surface 383 of the plurality of metal supports 380 to facilitate efficient saw blade cutting (at scribe lines, cutting through molding encapsulation 390 rather than the plurality of metal supports 380). Though five semiconductor packages are shown in the cross-sectional view of FIG. 3L, the number of semiconductor packages may vary. Though one contact pad is shown in the cross-sectional view of each semiconductor package of FIG. 3L, the number of contact pads may vary. For example, the semiconductor package 100 of FIG. 1 comprises five contact pads in the cross-sectional view. In one example, the singulation process is a laser cutting process (more expensive, melting metal debris around the sidewall of scribe line which may result to reliability test failure). In another example, the singulation process is a saw blade cutting process (cheaper, more reliable).

In examples of the present disclosure, each of the plurality of semiconductor packages 399 is a common-drain metal-oxide-semiconductor field-effect transistor (MOSFET) chip scale package (CSP) for battery protection application. In examples of the present disclosure, two gates and a plurality of sources are on a front surface of the common-drain MOSFET CSP. A common-drain is on a back surface of the common-drain MOSFET CSP.

Those of ordinary skill in the art may recognize that modifications of the embodiments disclosed herein are possible. For example, a total number of the plurality of contact pads 330 may vary. Other modifications may occur to those of ordinary skill in this art, and all such modifications are deemed to fall within the purview of the present invention, as defined by the claims.

1. A semiconductor package comprising:
a semiconductor substrate having a front surface and a back surface opposite the front surface of the semiconductor substrate;
a plurality of contact pads attached to the front surface of the semiconductor substrate;
a seed layer having a front surface and a back surface opposite the front surface of the seed layer, the front surface of the seed layer being directly attached to the back surface of the semiconductor substrate;
a metal support having a plurality of side surfaces, a front surface, and a back surface opposite the front surface of the metal support, the front surface of the metal support being directly attached to the back surface of the seed layer; and
a molding encapsulation directly contacting the plurality of side surfaces and the back surface of the metal support;
wherein a thickness of the semiconductor substrate is less than 50 microns; and
wherein a thickness of the metal support is at least 30 microns.

2. The semiconductor package of claim 1, wherein the thickness of the semiconductor substrate is in a range of 15 microns to 35 microns.

3. The semiconductor package of claim 1, edges of the molding encapsulation align with edges of the seed layer and edges of the semiconductor substrate.

4. The semiconductor package of claim 1, wherein the seed layer is composed of titanium.

5. The semiconductor package of claim 1, wherein the metal support is composed of copper.

6. The semiconductor package of claim 1, wherein the metal support is composed of sliver.

7. The semiconductor package of claim 1, wherein a thickness of the seed layer is in a range from 0.4 micron to 1.3 microns.

8. The semiconductor package of claim 1, wherein each of the plurality of contact pads contains nickel and gold.

9. The semiconductor package of claim 1, wherein the semiconductor package is a common-drain metal-oxide-semiconductor field-effect transistor (MOSFET) chip scale package (CSP) for battery protection application;
wherein two gates and a plurality of sources are on a front surface of the common-drain MOSFET CSP; and
wherein a common-drain is on a back surface of the common-drain MOSFET CSP.

10. A method for fabricating a plurality of semiconductor packages, the method comprising the steps of:
providing a device wafer comprising
a semiconductor substrate having a front surface and a back surface opposite the front surface of the semiconductor substrate; and
a plurality of contact pads attached to the front surface of the semiconductor substrate;
attaching a carrier to the plurality of contact pads of the device wafer;
applying a thinning process over the back surface of the semiconductor substrate so as to formed a thinned semiconductor substrate;
forming a seed layer on the thinned semiconductor substrate;
forming a photoresist coating layer on the seed layer;
etching the photoresist coating layer so as to form a patterned photoresist coating layer comprising a plurality of recesses exposing areas of the seed layer;
forming a plurality of metal supports overlaying the exposing areas of the seed layer in the plurality of recesses of the patterned photoresist coating layer;
removing the patterned photoresist coating layer so as to expose side surfaces of the plurality of metal supports;
forming a molding encapsulation directly contacting the side surfaces of the plurality of metal supports and back surfaces of the plurality of metal supports;
removing the carrier; and
applying a singulation process;
wherein a thickness of the thinned semiconductor substrate is in a range from 15 microns to 35 microns; and
wherein a thickness of each of the plurality of metal supports is at least 30 microns.

11. The method of claim 10, wherein the carrier is made of a metal material or a glass material; and wherein during the step of attaching a carrier to the plurality of contact pads of the device wafer, the attachment is by an adhesive layer surrounding and protecting the plurality of contact pads.

12. The method of claim 10, wherein the step of forming the molding encapsulation directly contacting the side surfaces of the plurality of metal supports and back surfaces of the plurality of metal supports further comprising a step of polishing process over the molding encapsulation so as to form a polished molding encapsulation.

13. The method of claim 10, wherein the thinning process includes grinding and etching.

14. The method of claim 10, wherein the seed layer contains titanium formed by sputtering.

15. The method of claim 10, wherein the plurality of metal supports contain copper formed by plating.

16. The method of claim 10, wherein the plurality of metal supports contain silver formed by plating.

17. The method of claim 10, wherein a thickness of the seed layer is in a range from 0.4 micron to 1.3 microns.

18. The method of claim 10, wherein each of the plurality of semiconductor packages is a common-drain metal-oxide-semiconductor field-effect transistor (MOSFET) chip scale package (CSP) for battery protection application;
wherein two gates and a plurality of sources are on a front surface of the common-drain MOSFET CSP; and
wherein a common-drain is on a back surface of the common-drain MOSFET CSP.

19. The method of claim 10, wherein the step of removing the patterned photoresist coating layer includes stripping.

20. The method of claim 10, wherein the step of applying the singulation process include saw blade cutting through the semiconductor substrate, the seed layer and the molding encapsulation in areas between adjacent metal supports.
